(19) United States
(12) Patent Application Publication
(10) Pub. No.: US 2002/0118853 A1
(43) Pub. Date: Aug. 29, 2002

(54) Loudspeaker enclosure with adjustable baffle board

(76) Inventor: Gunnar Flentje, Hamburg (DE)

Correspondence Address: GUNNAR FLENTJE, KIRCHENWEG 2, HAMBURG, 20099, DE

(21) Appl. No.: 09/982,888

(22) Filed: Oct. 22, 2001

Related U.S. Application Data
(63) Continuation of application No. 60/242,228, filed on Oct. 23, 2000.

(51) Int. Cl. H04R 1/02; H05K 5/00; H04R 9/06

(52) U.S. Cl. 381/336; 381/87; 181/150

(57) ABSTRACT

A loudspeaker enclosure is disclosed which includes a horizontal bottom wall, front wall means and parallel spaced vertical side walls connected with the bottom wall. The front wall means include an adjustable baffle board with at least one opening for mounting a loudspeaker and a horizontal top wall is connected with the upper edges of the front wall means and the side wails. Electronic components of a musical instrument amplifier may be mounted into the upper section of the enclosure. The invention is characterized by the provision of said adjustable baffle board which can be vertically tilted backwards or, as an alternative, sidewise to change the listening axis from the loudspeaker to the listener for optimum directional sound quality. The enclosure further has either at least four contact members or defines one complete contact surface relative to a support surface to let vibrational energy propagate freely throughout the cabinet and be transferred to said support surface, thus causing additional vibration therein. The user may reorient the baffle board depending upon the position of the loudspeaker relative to the listeners ear level without cutting off the transmission of structure-born sound from the cabinet to the support surface.

### CROSS-REFERENCE TO RELATED APPLICATIONS

This application is claiming the benefits of my provisional patent application titled “Guitar Amplifier with Volume Control and tiltable Loudspeaker”, appl. No. 60/242,228 filed Oct. 23, 2000.

### TECHNICAL FIELD

This invention relates in general to audio amplifier cabinets with loudspeaker arrangements, and more particularly, to musical instrument amplifiers such as guitar amplifiers.

### BACKGROUND OF INVENTION

Musicians who play electrified instruments need to use electrical amplifiers and associated loudspeaker cabinets to be audible in a performance. In fact, these amplifiers not only amplify the original sound of the instrument, but very often add different tonality and thus make a significant part of the player's individual sound. Very popular among, for example, guitar players are amplifier/loudspeaker combinations which create a certain “open” but yet rich sound. These combo amps are easy to handle and don't take much space on small stages. But also traditional set-up combinations of an amplifier being placed on top of a speaker cabinet are in wide use.

Unfortunately, a basic problem that these players of electrical amplified instruments face, is the often problematic audibility in several situations due to the limited directional sound characteristics of their amplifier/loudspeaker combinations or loudspeaker cabinets. Especially guitar players traditionally perform standing up with their amplifiers sitting on the floor, which makes it hard for them to monitor their playing.

In order to achieve better audibility, amps are often placed on a chair, a transport box or onto some kind of stand to facilitate raising the amplifier closer to the player's ear level. Sometimes tilt-back stands are used to aim the amplifier upward at some desired angle, thus allowing the player to better hear himself play, as opposed to the sound basically beaming out of the speakers at knee-level when the equipment is sitting on the floor. Also, guitar amplifiers or loudspeaker cabinets have been provided with pivotable metal rods in order to allow tilting back of the complete enclosure on the floor. A good example for this prior art features some more sophisticated means for supporting an amplifier in such a tilted angle and is shown in U.S. Pat. No. 6,101,261 by Brown and James.

Yet all of the previous attempts to solve the problem of satisfying audibility have one major shortcoming in common. Not only is it very inconvenient for players to eventually have to take care for an additional height support of their equipment, but there is also a very significant reason for why most players still keep their amps or cabinets on the floor.

Guitar amplifiers or loudspeaker cabinets usually consist of rectangular, preferably wooden boxes with the electronic components and/or the actual loudspeakers mounted therein. The working loudspeakers emit sound but also cause the wooden cabinet surfaces to resonate at certain frequencies, which adds a significant portion to the sound characteristics of a particular amplifier or cabinet.

Usually these “sounding” wooden boxes are standing upright connected with at least four support members or one complete surface to their support surface, which is usually a wooden stage or the like. In this position a large portion of vibrational energy propagates freely throughout the cabinet and is transferred to the support surface, thus causing additional vibration therein. This structure-born sound in conjunction with the speaker sound and the resonating cabinet sound adds up to the overall sound characteristics associated with a certain type of amplifier or speaker enclosure.

Depending on construction and situation of placement, mostly low frequencies (in a range from 0-600 Hz) are randomly added and certain, normally unwanted effects of acoustic distortion occur and make musical instrument combo amplifiers and speaker cabinets sound “full” and “rich”, especially when they are designed as open enclosures. Players explicitly like this acoustic behavior of their equipment because they feel more dynamic response and claim to have an almost “tangible” tone, if vibrations of their amp or cabinet are not being isolated from the supporting surface but resonate therein. Although thoroughly avoided in HiFi applications, this effect of structure-born sound has become a particular trademark and part of the typical sound of amplified electric guitar and many other electrified instruments.

If amplifiers or cabinets are tilted back or placed upon stands, the transmission of structure-born sound is partially or completely cut off Players have to deal with a lack of certain frequencies in the overall sound characteristics that they are used to and perceive their amps or cabinets to sound “thin” or “weak”. Accordingly most instrumentalists don't like to tilt back their equipment for this main and several other reasons.

If musicians elevate their amplifiers and speakers off of the floor by utilizing makeshift stands such as stools, chairs, boxes, and the like, this often results in accidents when the amplifiers are accidentally knocked off the stand or pulled off of the stand by cables connected thereto.

Tilting back a loudspeaker cabinet or combo amp takes at least twice, usually up to three times as much floor space as if the same equipment would be placed upright. This is extremely inconvenient on a small stage or in a practice room with limited space capacity.

Tilting back a working guitar amplifier cuts off the upward air stream of heat dissipation around the enclosure and heat congestion in the top part occurs. Because the electronic components of a combo amp are usually mounted into the upper section of its enclosure, this may lead to overheating the circuit and therefore can cause severe damage to the amplifier.

Tilting back a loudspeaker cabinet is similarly undesirable because players usually place the connected amplifier right on top of it to have easy access to the controls during their performances. This obviously would be impossible if the cabinet is tilted back, unless the amplifier would be mounted in a fixed conjunction onto it.

Also, due to limited space especially on small stages, players also commonly use the horizontal surfaces of their equipment to place their accessories on.

All the above discussed shortcomings of prior art equipment lead to a constant conflict for a players, as they either have to sacrifice audibility and monitoring or safety and sound quality. It is therefore highly desirable to provide an instrument amplifier or a loudspeaker cabinet that has adjustable directional sound characteristics when it is placed upright and acoustically connected to a supporting surface.

### SUMMARY OF THE INVENTION

Object of the present invention is to provide a musicians amplifier or loudspeaker enclosure that permits the musician to adjust the directivity of the sound by altering the listening axis of the loudspeaker (i.e., a line from the center of the loudspeaker to the center of the listener's head at ear level) towards a desired direction without having to remove the enclosure from its upright position. Although certain situations may require also a sidewise orientation, the preferred embodiment of the present invention allows changing the listening axis of the loudspeaker upward or downward, depending upon the height of the loudspeaker relative to the listener's ear level.

In accordance with the present invention, there is provided a loudspeaker cabinet with an adjustable baffle board. While the invention may be utilized with any type of speaker enclosure wherein no electronic means is disposed within the enclosure, it is especially adapted to be utilized as a guitar amplifier because it is particularly convenient that the enclosures of guitar amplifiers be provided with some means for altering the listening axis of the loudspeaker.

Although of structure-born sound is a crucial factor for good guitar sound, the prior art does not show any amplifiers or loudspeaker enclosures with a possibility to alter the listening axis of the loudspeaker without cutting off the transmission of structure-born sound from the enclosure to its support surface. This is achieved by the further disclosed invention.

The enclosure of the present invention has either an adjustable baffle board and additional wall means to maintain airtightness of the cabinet or features an adjustable baffle board in form of an acoustically coupled subcabinet within the main enclosure, which will be referred to as the preferred embodiment of the invention in the following detailed disclosure. Manually operable lock members can be loosened even during a continuing performance, thus allowing the player a convenient reorientation of the baffle board and therefore the listening axis of the loudspeaker. If the desired angel is found, the baffle board or subcabinet can be conveniently fixed in its position by re-tightening the lock means

The cabinet is maintained in an upright position at all times and the “full” sound of the enclosure is never impaired. There is no danger of overheating the amplifier or dropping equipment or accessories placed thereon and a perfect direction of sound to the players ear can be achieved even on a very small or very crowded stage. Also, such an enclosure is easy to handle, conveniently to use and no extra equipment is necessary. Manufacturing of such an enclosure would be inexpensively to achieve since no expensive special parts are needed.

Additional objects and advantages of the invention will be set forth in part in the description that follows, and in part will become apparent to those skilled in the art upon examination of the following or may be learned by practice of the invention.

### DESCRIPTION OF DRAWINGS

FIG. 1 shows a prior art construction in a tilted position

FIG. 2 is a view similar, illustrating the preferred embodiment of the invention

FIG. 3 shows a guitar player using a prior art amplifier support construction

FIG. 4 shows a guitar player using a construction as shown in FIG. 1

FIG. 5 shows a guitar player using the preferred embodiment of the present invention on a medium large stage

FIG. 6 shows a guitar player using the preferred embodiment of the present invention on an average small stage

FIG. 7 is a top perspective view of the preferred embodiment of the present invention with the baffle board in a transport or initial position

FIG. 8 is a top perspective view of the preferred embodiment of the present invention with the baffle board in an angular position

FIG. 9 is an exploded view of the preferred embodiment of the present invention

FIG. 10 is a top perspective view of a second preferred embodiment of the present invention with the baffle board in an angular position

FIG. 11 is a top perspective view of a third preferred embodiment of the present invention with the baffle board in an angular position

### DESCRIPTION OF THE INVENTION

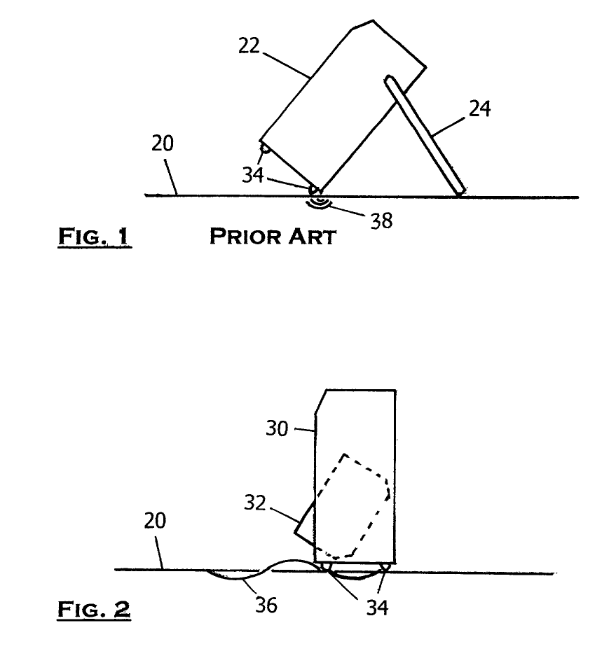

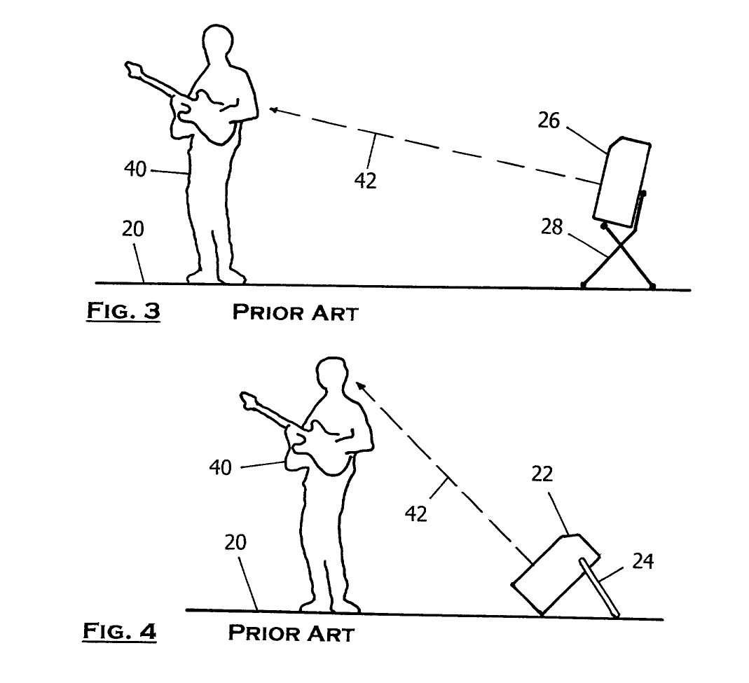

FIG. 1 shows a prior art amplifier 22 with tilt back legs 24 on a support surface 20. The amp is equipped with supporting contact members which also transmit structure born sound 38 to the contact surface 20. Because the amplifier is tilted back, the transmission of structure born sound is cut off. The enclosure 30 of the preferred embodiment of the present invention does not need to be tilted back in order to achieve alteration of the listening axis of the loudspeaker. The provided adjustable baffle board on the adjustable subcabinet can be tilted back individually and structure born sound 36 is completely transmitted by supporting contact members 34.

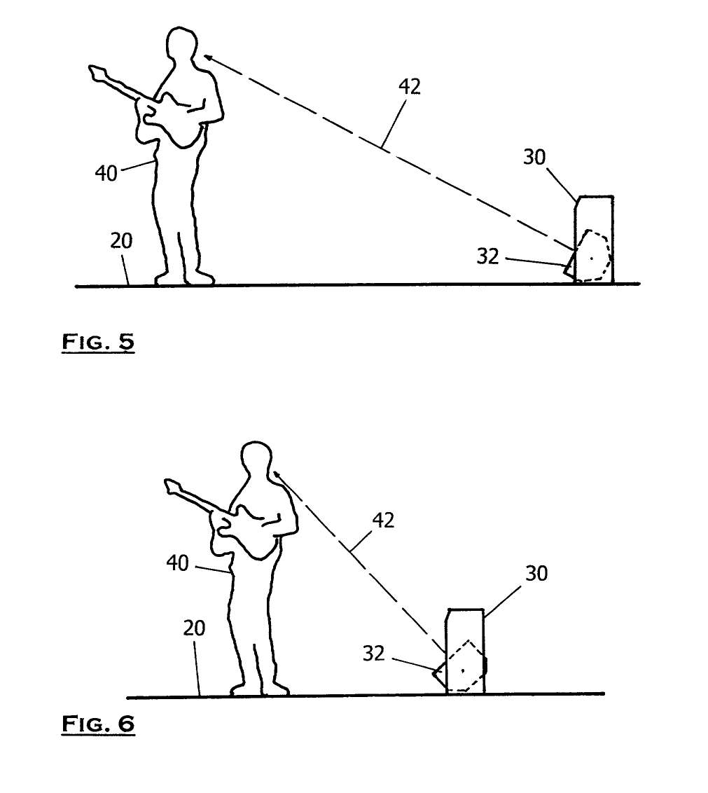

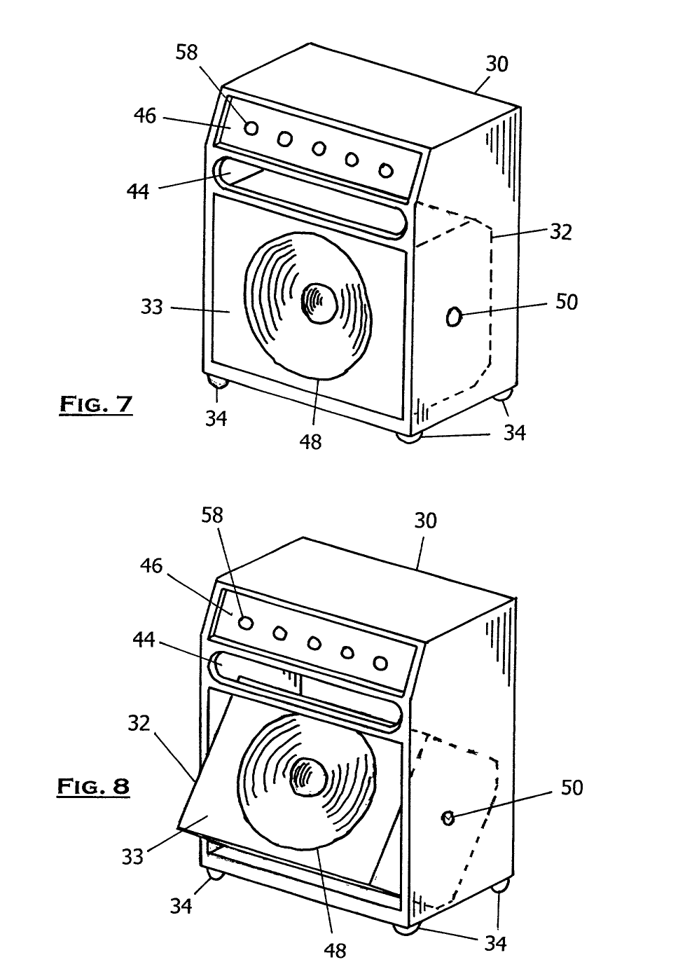

If a guitar player 40 uses either such an enclosure 22, as shown in FIG. 4, or decides to use a portable support stand 28 as shown in FIG. 3 there is no transmission of structure born sound and usually the listening axis 42 is maintained adjusted at a constant angle. FIG. 5 and 6 show a guitar player using the enclosure of the present invention. The adjustable baffle board on the adjustable subcabinet 32 can be fixed in a plurality of multiple angular positions, thus allowing convenient adjustment of the listening axis to the players ear level on a small stage (FIG. 6) as well as on a larger stage (FIG. 5.) The transmission of structure born sound is never interrupted.

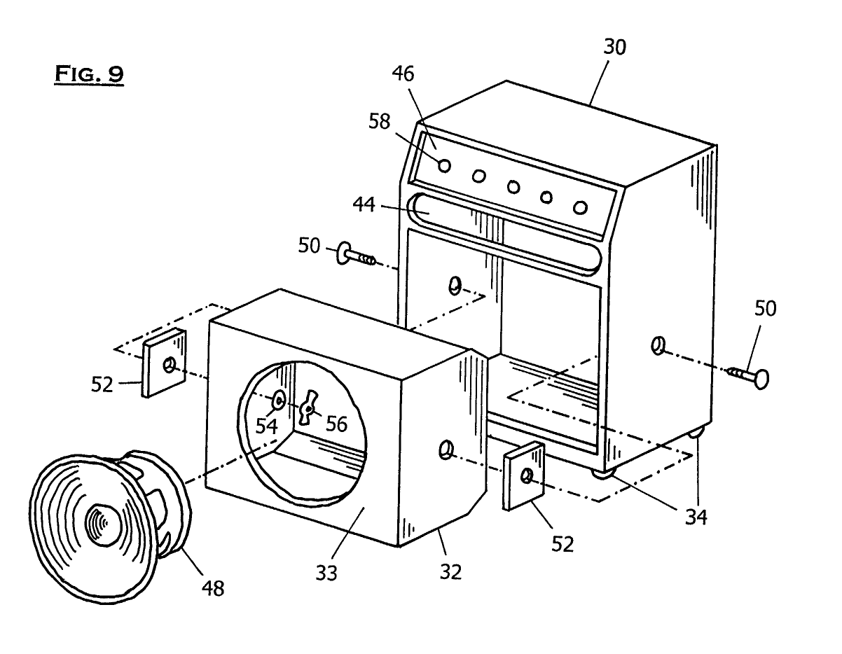

FIG. 7 shows the enclosure 30 of the present invention in a transport or initial position. The baffle board 33 with loudspeaker 48 is maintained in an upright position due to the subcabinet 32 being locked vertically by lock members (shown in FIG. 9) attached oppositely to pivot bolts 50. If, as shown in FIG. 8, the subcabinet 32 is tilted back, sound can be emitted freely, also passing through sound opening 44 and not being reflected by amplifier chassis 46 which contains the electric circuit for amplification. Also, the control elements 58 of the amplifier 46 can still be conveniently reached in tilt-back mode.

FIG. 9 depicts the lock mechanism comprising pivot bolts 50, washers 54 and locknuts 56. Large contact members 52 are installed to maintain transmission of structure born sound from subcabinet 32 to enclosure 30 constant.

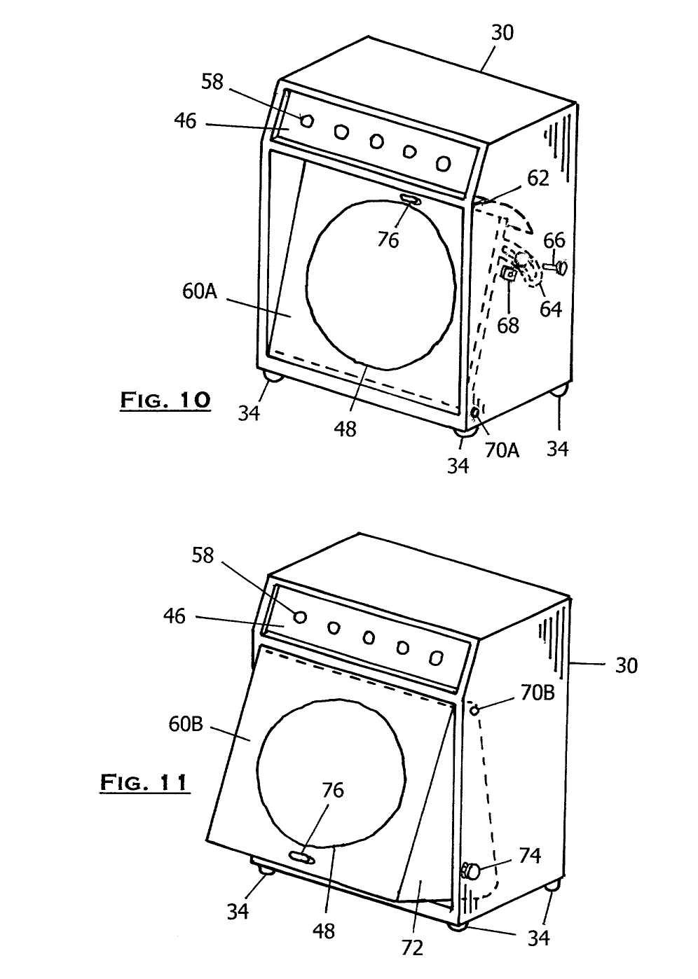

FIG. 10 shows a second preferred embodiment of the present invention. The adjustable baffle board 60A is supported with pivot rods 70A and can be tilted back. An arched plane 62 mounted underneath the amp chassis 46 maintains the enclosure 30 airtight when the baffle board 60A is tilted back. Metal fittings 64 mounted vertically on the backside of the baffle board 60A can be fixed to the enclosure by tightening bolts 66 to rectangular locknuts 68 which slide within a groove in the metal fittings 64. In order to achieve convenient adjustment, a handle 76 is mounted on the baffle board.

FIG. 10 shows a second preferred embodiment of the present invention. The adjustable baffle board 60B is supported with pivot rods 70B and can be tilted upwardly out of the enclosure 30 with a handle 76 mounted thereto. Additional side walls 72 and a bottom wall (not shown) are mounted vertically to the baffle board 60B to maintain the cabinet airtight. The baffle board 60B can be fixed to the enclosure by tightening screws 74 which put pressure on the sidewalls 72 to hold the baffle board in a desired angular position.

### OPERATION OF THE INVENTION

Since most guitar amplifiers are less than 23 inches in height, the enclosure of the amplifier usually sits on a support surface such as the floor with the loud speakers facing forward and directed essentially parallel to the floor. This makes it hard for the player to hear himself play because the sound is basically beaming out of the speakers at knee-level or, when the amplifier is placed on a chair, at hip-level.

The present invention provides a guitar amplifier cabinet 30 with means for tilting the baffle board backwards in order to have the sound beaming upward at a convenient angle for the musician to enhance monitoring or his playing. A guitarist who performs on a small stage can unlock the baffle board, which then can be tilted backwards and can be locked in several positions to provide a variety of different angels for the loudspeaker to aim and upwards or sidewards, if desired. The guitarist can easily set the listening axis of the loudspeaker without having to tilt back the complete enclosure. This is extremely helpful on a small stage or when the player works in an orchestra.

This novel guitar amplifier is easy to make and would make a significant difference to many guitar players. Further adaptations or minor modifications within the spirit of the invention will be apparent to those skilled in the art. Also, from the foregoing disclosure, those skilled in the art might devise many uses and modifications of the present invention. It is, therefore, intended that the scope of the present invention be not limited by the foregoing specification, but rather only by the appended claims.

List of Reference Numbers

| | |
|---|---|
| support surface | 20 |
| prior art enclosure | 22 |
| metal rod | 24 |
| regular enclosure | 26 |
| prior art amplifier stand | 28 |
| loudspeaker enclosure | 30 |
| subcabinet | 32 |
| baffle board | 33 |
| supporting contact member | 34 |
| structure-born sound waves | 36 |
| sound waves | 38 |
| guitar player | 40 |
| listening axis | 42 |
| sound opening | 44 |
| amplifier chassis | 46 |
| loudspeaker | 48 |
| pivot bolt | 50 |
| contact member | 52 |
| washer | 54 |
| locknut | 56 |
| control element | 58 |
| baffle board | 60A |
| baffle board | 60B |
| arched plane | 62 |
| metal fitting | 64 |
| bolt | 66 |
| rectangular locknut | 68 |
| pivot rod | 70A |
| pivot rod | 70B |
| baffle hoard sidewall | 72 |
| tightening screw | 74 |
| handle | 76 |

What claimed is:

1. A loudspeaker enclosure, including means to transmit structure born sound to a support surface, further including means for altering the listening axis from the loudspeaker to the listener for optimum directional sound quality, said loudspeaker enclosure comprising:
bottom wall means comprising means to transfer structure-born vibrational energy from said enclosure to said support surface;
front wall means which define, together with said bottom wall means and a plurality of walls, an enclosure;
said front wall means including an adjustable baffle board with at least one opening for mounting a loudspeaker transducer,
said adjustable baffle board having an infinite plurality of angular positions relative to said bottom wall means or relative to one wall of said plurality of walls, and said adjustable baffle board defining in an initial position a vertical plane relative to said bottom wall means and relative to said one wall,
pivot means supporting said adjustable baffle board for a predetermined range of swivel movement relative to said vertical plane through predetermined angles about a predetermined axis located within or at predetermined distance rearwardly from said vertical plane, and
means for locking said adjustable baffle board in an infinite plurality of fixed angular positions relative to said vertical plane within said predetermined range of swivel movement,
whereby the orientation of the baffle board can be adjusted to change the listening axis of the loudspeaker (i.e., a line from the center of the loudspeaker to the center of the listener's head at ear level) without cutting off the transmission of structure-born sound from the cabinet to the support surface.

2. The loudspeaker enclosure of claim 1, wherein said bottom wall means defining a parallel plane relative to the support surface, thereby providing a contact surface to transfer said structure-born vibrational energy from the enclosure to the support surface.

3. The loudspeaker enclosure of claim 1, wherein
said bottom wall means including a plurality of support members, said support members defining a plurality of contact members to transfer said structure-born vibrational energy from the enclosure to the support surface.

4. The loudspeaker enclosure of claim 1, wherein
two walls of said plurality of walls defining the enclosure or one wall of said plurality of walls and said bottom wall means together define a pair of parallel enclosure walls.

5. The loudspeaker enclosure of claim 4, wherein
said pivot means comprising a pair of metal rods, said rods being mounted into said pair of parallel enclosure walls, and
said adjustable baffle board further comprising a handle for easy adjustment, and
said adjustable baffle board further comprising a plurality of additional wall members attached vertically thereto, said additional wall members being adapted to maintain airtightness of the enclosure when the baffle board is being moved out of its initial position for adjustment, and
two of said additional wall members defining a pair of parallel baffle board walls, said parallel baffle board walls sliding adjacent along said pair of parallel enclosure walls during adjustment of said baffle board, and
said means for locking said adjustable baffle board in said infinite plurality of fixed angular positions comprising a pair of tightening screws, said tightening screws being supportedly mounted in said parallel enclosure walls to put pressure upon said adjacent parallel baffle board walls for locking the baffle board in a predetermined angular position.

6. The loudspeaker enclosure of claim 4, wherein
said adjustable baffle board further comprising a plurality of additional wall members mounted vertically thereto, said additional wail members in conjunction with the adjustable baffle board defining an open subcabinet having at least one pair of parallel subcabinet walls,
said parallel subcabinet walls being acoustically coupled to said parallel enclosure walls with contact members, said contact members transferring structure-born vibrational energy from the subcabinet to the enclosure, and
said pivot means comprising a pair of bolts supporting said subcabinet, said bolts being mounted into said pair of parallel enclosure walls, and
said means for locking said adjustable baffle board in said infinite plurality of fixed angular positions comprising a pair of locknuts and washers, said locknuts matching said bolts and being mounted thereon from within the cavity defined by the open subcabinet,
whereby the subcabinet can be fixed to the enclosure via said contact members by tightening the locknuts to the bolts, thereby locking the baffle board in a predetermined angular position.

7. The loudspeaker enclosure of claim 4, wherein
said adjustable baffle board further comprising a plurality of additional wall members, said additional wall members in conjunction with the adjustable baffle board defining a subcabinet naving at least one pair of parallel subcabinet walls,
said parallel subcabinet walls being acoustically coupled to said parallel enclosure walls with contact members, said contact members transferring structure-born vibrational energy from the suboabinet to the enclosure, and
said pivot means comprising a pair of bolts supporting said subcabinet, said bolts being supportedly mounted into said pair of parallel enclosure walls, and
said means for locking said adjustable baffle board in said infinite plurality of fixed angular positions comprising said bolts and a pair of locknuts, said locknuts matching said bolts and being mounted in the parallel subcabinet walls in a fixed positions,
whereby the baffle board can be locked in a predetermined angular position by tightening the supportedly mounted bolts within the enclosure walls to the fixed nuts within the subcabinet walls.

8. The loudspeaker enclosure of claim 4, wherein
said pivot means comprising a pair of metal rods, said rods being mounted into said pair of parallel enclosure walls, and
said adjustable baffle board further comprising a handle for easy adjustment, and
said adjustable baffle board further comprising a pair of metal fittings being vertically attached to the baffle board, said metal fittings sliding parallel along said parallel enclosure walls during adjustment of said baffle board and said fittings having slots and grooves along their length and being bow-shaped, and
said means for locking said adjustable baffle board in an infinite plurality of fixed angular positions comprising a pair of bolts being mounted in said parallel enclosure walls, further comprising corresponding rectangular locknuts, said rectangular locknuts sliding within said grooves of said metal fittings and said bolts being attached through said slots in said fittings and being fixed to said rectangular locknuts, thereby fixing the metal fittings to the enclosure and locking the baffle board in a predetermined angular position.

9. The loudspeaker enclosure of claim 8, wherein
said adjustable baffle board having one edge opposite to its supporting axis, said edge sliding along an arched plane within the enclosure during adjustment of the adjustable baffle board,
said arched plane being mounted in the top part of said enclosure to maintain air tightness of the enclosure when said adjustable baffle board is moved out of its initial position,

10. A loudspeaker enclosure, including means to transmit structure born sound to a support surface, further including means for altering the listening axis from the loudspeaker to the listener for optimum directional sound quality, said loudspeaker enclosure comprising
bottom wall means comprising means to transfer structure-born vibrational energy from said enclosure to said support surface;
front wall means which define, together with said bottom wall means and a plurality of walls, an enclosure;
said front wall means including an adjustable baffle board with at least one opening for mounting a loudspeaker transducer,
said adjustable baffle board having an infinite plurality of angular positions relative to said bottom wall means or relative to one wall said plurality of walls, and said adjustable baffle board defining in an initial position a vertical plane relative to said bottom wall means and relative to said one wall,
pivot means supporting said adjustable baffle board for a predetermined range of swivel movement relative to said vertical plane through predetermined angles about a predetermined axis located within or at predetermined distance rearwardly from said vertical plane, and
means for locking said adjustable baffle board in an infinite plurality of fixed angular positions relative to said vertical plane within said predetermined range of swivel movement, and
means for housing an electronic circuit for audio amplification, comprising a metall chassis, said metal chassis being mounted into the enclosure, supporting audio amplifier control means, said control means being located within or near said vertical plane,
whereby the orientation of the baffle board can be adjusted to change the listening axis of the loudspeaker (i.e., a line from the center of the loudspeaker to the center of the listeners head at ear level) without cutting off the transmission of structure-born sound from the cabinet to the support surface.

11. The loudspeaker enclosure of claim 10, wherein
said bottom wall means defining a parallel plane relative to the support surface, thereby providing a contact surface to transfer said structure-born vibrational energy from the enclosure to the support surface.

12. The loudspeaker enclosure of claim 10, wherein
said bottom wall means including a plurality of support members, said support members defining a plurality of contact members to transfer said structure-born vibrational energy from the enclosure to the support surface.

13. The loudspeaker enclosure of claim 10, wherein
two walls of said plurality of walls defining the enclosure or one wall of said plurality of walls and said bottom wall means together define a pair of parallel enclosure walls.

14. The loudspeaker enclosure of claim 13, wherein
said pivot means comprising a pair of metal rods, said rods being mounted into said pair of parallel enclosure walls, and
said adjustable baffle board further comprising a handle for easy adjustment, and
said adjustable baffle board further comprising a plurality of additional wall members attached vertically thereto, said additional wail members being adapted to maintain airtightness of the enclosure when the baffle board is being moved out of its initial position for adjustment, and
two of said additional wall members defining a pair of parallel baffle board walls, said parallel baffle board walls sliding adjacent along said pair of parallel enclosure walls during adjustment of said baffle board, and
said means for locking said adjustable baffle board in said infinite plurality of fixed angular positions comprising a pair of tightening screws, said tightening screws being supportedly mounted in said parallel enclosure walls to put pressure upon said adjacent parallel baffle board walls for locking the baffle board in a predetermined angular position.

15. The loudspeaker enclosure of claim 13, wherein
said adjustable baffle board further comprising a plurality of additional wall members mounted vertically thereto, said additional wall members in conjunction with the adjustable baffle board defining an open subcabinet having at least one pair of parallel subcabinet walls,
said parallel subcabinet walls being acoustically coupled to said parallel enclosure walls with contact members, said contact members transferring structure-born vibrational energy from the subcabinet to the enclosure, and
said pivot means comprising a pair of bolts supporting said subcabinet, said bolts being mounted into said pair of parallel enclosure walls, and
said means for locking said adjustable baffle board in said infinite plurality of fixed angular positions comprising a pair of locknuts and washers, said locknuts matching said bolts and being mounted thereon from within the cavity defined by the open subcabinet,
whereby the subcabinet can be fixed to the enclosure via said contact members by tightening the locknuts to the bolts, thereby locking the baffle board in a predetermined angular position.

16. The loudspeaker enclosure of claim 13, wherein
said adjustable baffle board further comprising a plurality of additional wall members, said additional wall members in conjunction with the adjustable baffle board defining a subcabinet having at least one pair of parallel subcabinet walls,
said parallel subcabinet walls being acoustically coupled to said parallel enclosure walls witn contact members, said contact members transferring structure-born vibrational energy from the suboabinet to the enclosure, and
said pivot means comprising a pair of bolts supporting said subcabinet, said bolts being supportedly mounted into said pair of parallel enclosure walls, and
said means for locking said adjustable baffle board in said infinite plurality of fixed angular positions comprising said bolts and a pair of locknuts, said locknuts matching said bolts and being mounted in the parallel subcabinet walls in a fixed positions,
whereby the baffle board can be locked in a predetermined angular position by tightening the supportedly mounted bolts within the enclosure walls to the fixed nuts within the subcabinet walls.

17. The loudspeaker enclosure of claim 13, wherein
said pivot means comprising a pair of metal rods, said rods being mounted into said pair of parallel enclosure walls, and
said adjustable baffle board further comprising a handle for easy adjustment, and
said adjustable baffle board further comprising a pair of metal fittings being vertically attached to the baffle board, said metal fittings sliding parallel along said parallel enclosure walls during adjustment of said baffle board and said fittings having slots and grooves along their length and being bow-shaped, and
said means for locking said adjustable baffle board in an infinite plurality of fixed angular positions comprising a pair of bolts being mounted in said parallel enclosure walls, further comprising corresponding rectangular locknuts, said rectangular locknuts sliding within said grooves of said metal fittings and said bolts being attached through said slots in said fittings and being fixed to said rectangular locknuts, thereby fixing the metal fittings to the enclosure and locking the baffle board in a predetermined angular position.

18. The loudspeaker enclosure of claim 17, wherein
said adjustable baffle board having one edge opposite to its supporting axis, said edge sliding along an arched plane within the enclosure during adjustment of the adjustable baffle board,
said arched plane being mounted in the top part of said enclosure to maintain air tightness of the enclosure when said adjustable baffle board is moved out of its initial position.
